(19) United States
(12) Patent Application Publication
(10) Pub. No.: US 2003/0221153 A1
(43) Pub. Date: Nov. 27, 2003

(54) Shmoo plot evaluation method with a relief analysis

(75) Inventor: Yasuhiko Fukushima, Tokyo (JP)

Correspondence Address: McDermott, Will & Emery, 600 13th Street, N.W., Washington, DC, 20005-3096, US

(73) Assignee: Mitsubishi Denki Kabushiki Kaisha

(21) Appl. No.: 10/295,915

(22) Filed: Nov. 18, 2002

(30) Foreign Application Priority Data
May 24, 2002 (JP) 2002-150594

(51) Int. Cl. G06F 11/00; G01R 31/28

(52) U.S. Cl. 714/742

(57) ABSTRACT

Shmoo conditions are set in a Shmoo plot tool and Shmoo plot is started. Initial parameter values are set in tester hardware. A test is performed by using set parameter values. A step in which fail information that is produced as a result of the test is transferred to a relief analysis apparatus. The relief analysis apparatus performs a relief analysis on defective bits. A result of the relief analysis is transferred to the Shmoo plot tool. The Shmoo plot tool outputs a result of the relief analysis as Shmoo data. The step of performing the test and the following steps are repeated while the set parameter values are changed.

### BACKGROUND OF THE INVENTION

1. Field of the Invention

The present invention relates to a Shmoo plot evaluation method with a relief analysis.

2. Description of the Background Art

The Shmoo plot is well known as a technique of electrical characteristic evaluation on a semiconductor chip. In the Shmoo plot, tests are repeated while one or a plurality of test conditions and parameters are varied at arbitrary time points during execution of a test program. Test results (passes and fails) are output in the form of a plot diagram, and are used for judging operation margins for design targets and product specifications and for finding out an abnormal operation, a problem in design, or the like based on the form of operation area. An example of the plot diagram will be described later.

FIG. 8 is a block diagram showing a general configuration of a tester system that performs Shmoo plot.

In FIG. 8, reference numeral 1 denotes basic software for operating the system having a user interface processor 1A and OS/system software 1B. Reference numeral 2 denotes a user interface such as a keyboard for interactive processing. Reference numeral 3 denotes control software having a tester control processor 3A and a tester utility 3B for activating a Shmoo plot tool.

Reference numeral 4 denotes a tester hardware that is controlled by the tester control processor 3A. Reference numeral 5 denotes a device under test.

To perform Shmoo plot, the Shmoo plot tool is activated by the tester utility 3B and conditions are set through the user interface 2 in an interactive manner. The tester control processor 3A performs Shmoo plot by controlling the tester hardware 4 according to the conditions thus set.

An example of Shmoo plot execution procedure will be described below with reference to a flowchart of FIG. 9.

At step S1, a test program is started according to an instruction from the user interface 2. At step S2, the test program is executed and temporarily suspended at a test item that was specified in advance.

At step S3, the Shmoo plot tool is activated. At step S4, Shmoo conditions, for example X-axis and Y-axis parameters, are set through the user interface 2 in an interactive manner and Shmoo plot is started. At step S5, initial parameter values are set in the tester hardware 4. At step S6, a test is performed. At step S7, a test result is output (displayed). Steps S6 and S7 are repeated again after the values of the X-axis and Y-axis parameters are changed. FIG. 10 shows an example of Shmoo plot output (display) of test results in which the X axis represents a rate (timing) and the Y axis represents Vdd (voltage). In FIG. 10, symbol “.” denotes a pass and symbol “*” denotes a fail.

Incidentally, in tests on memories or the memory portions of system LSIs or the like each incorporating a memory, there is a tendency that the all-pass (i.e., a good product is obtained without any repair relief) ratio is decreasing with recent increase in the degree of miniaturization in wafer processes and increase in the integration density of memories.

In the above circumstances, to increase the yield on the device side, memory relief techniques are now employed that convert slightly defective chips into good ones by providing each chip with redundant memory cells in advance and replacing defective primary memory cells with redundant ones by known laser trimming (LT) in a wafer trimming step.

However, in a pre-LT test that is performed prior to LT, a memory chip is subjected to a function test. If the judgment result is “defective,” defective bit information is transferred to a relief analysis apparatus and it judges whether the memory chip can be relieved by replacing defective memory cells with redundant ones that are held by the memory chip. If the defects are so slight as to allow relief, it is judged that the chip is a good one (hereinafter referred to as “repair-good chip (or device) ”) in the pre-LT test, that is, before conversion into a good chip by LT. Therefore, devices including repair-good ones will be subjected to the evaluation by the Shmoo plot tool.

However, the above-described Shmoo plot tool cannot acquire data unless a chip is a completely good one under variable test conditions of Shmoo plot. This results in a problem that the Shmoo plot tool cannot be applied to a repair-good chip until the chip is relieved by LT. This leads to a problem that the efficiency of electrical characteristic evaluation is very low in devices that heavily rely on the redundancy relief, such as leading-edge-process devices and large-capacity memory devices.

### SUMMARY OF THE INVENTION

The present invention has been conceived to solve the previously-mentioned problems and a general object of the present invention is to provide a novel and useful Shmoo plot evaluation method.

A more specific object of the present invention is to provide a Shmoo plot evaluation method that can also be applied to repair-good devices that have not been relieved by LT yet.

The above object of the present invention is attained by a following Shmoo plot evaluation method.

According to a first aspect of the present invention, in the Shmoo plot evaluation method in a tester comprising a Shmoo plot tool and a relief analysis apparatus, Shmoo conditions are set in the Shmoo plot tool and Shmoo plot is started. Initial parameter values are set in a tester hardware. A test is performed using set parameter values. Fail information that is produced as a result of the test is transferred to the relief analysis apparatus. The relief analysis apparatus is caused to perform a relief analysis on defective bits. A result of the relief analysis is transferred to the Shmoo plot tool. The Shmoo plot tool is caused to output a result of the relief analysis as Shmoo data. Wherein the step of performing a test and the following steps are repeated while the set parameter values are changed.

According to a second aspect of the present invention, in the Shmoo plot evaluation method in a tester comprising a Shmoo plot tool and a relief analysis apparatus, Shmoo conditions are set in the Shmoo plot tool and starting Shmoo plot is started. Initial parameter values are set in a tester hardware. A test is performed using set parameter values. Fail information that is produced as a result of the test is transferred to the relief analysis apparatus. The relief analysis apparatus is caused to perform a relief analysis on defective bits. The Shmoo plot tool is caused to perform, parallel with the relief analysis, a next test after the set parameter values are changed. A result of the relief analysis is transferred to the Shmoo plot tool. The Shmoo plot tool is caused to output a result of the relief analysis as Shmoo data. Wherein the step of performing a test and the following steps are repeated while the set parameter values are changed.

According to a third aspect of the present invention, in the Shmoo plot evaluation method in a tester comprising a Shmoo plot tool and a relief analysis apparatus, setting Shmoo conditions in the Shmoo plot tool and starting Shmoo plot; initial parameter values are set in a tester hardware. A test is performed using set parameter values. Fail information that is produced as a result of the test is transferred to the relief analysis apparatus. The relief analysis apparatus is caused to perform a relief analysis on defective bits. A mask for masking defective addresses is set for the relief analysis apparatus. Completion of setting of the mask is transferred to the Shmoo plot tool. The Shmoo plot tool is caused to start a Shmoo plot test. Fail information that is produced as a result of the Shmoo plot test is transferred to the relief analysis apparatus. The relief analysis apparatus in which the mask is set is caused to perform a relief analysis on defective bits. A result of the relief analysis is transferred to the Shmoo plot tool. The Shmoo plot tool is caused to output, as Shmoo data, a result of the relief analysis with the mask. Wherein the step of causing the Shmoo plot tool to start a Shmoo plot test and the following steps are repeated while the set parameter values are changed.

Other objects and further features of the present invention will be apparent from the following detailed description when read in conjunction with the accompanying drawings.

### BRIEF DESCRIPTION OF THE DRAWINGS

FIG. 1 is a block diagram showing a general configuration of a tester system according to First Embodiment of the present invention;

FIG. 2 is a flowchart showing a Shmoo plot execution procedure according to First Embodiment of the present invention;

FIG. 3 is a separated operation flows of a tester and a relief analysis apparatus;

FIG. 4 is a flowchart showing a Shmoo plot execution procedure according to Second Embodiment of the present invention;

FIG. 5 is a flowchart showing a Shmoo plot execution procedure according to Third Embodiment of the present invention;

FIG. 6 is a view showing an example of Shmoo plot output;

FIG. 7 is a view showing other example of Shmoo plot output;

FIG. 8 is a block diagram showing a general configuration of a tester system that performs Shmoo plot;

FIG. 9 is a flowchart showing an example of Shmoo plot execution procedure; and

FIG. 10 is a view showing an example of Shmoo plot output.

### DETAILED DESCRIPTION OF THE PREFERRED EMBODIMENTS

In the following, principles and embodiments of the present invention will be described with reference to the accompanying drawings. The members and steps that are common to some of the drawings are given the same reference numerals and redundant descriptions therefore may be omitted.

First Embodiment

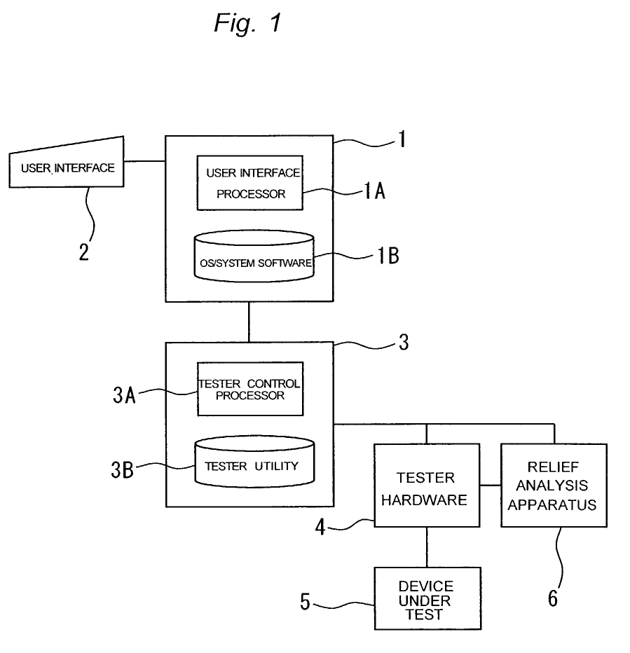

First Embodiment of the present invention will be hereinafter described with reference to the drawings. FIG. 1 is a block diagram showing a general configuration of a tester system according to First Embodiment of the present invention.

In FIG. 1, reference numeral 1 denotes basic software for operating the system having a user interface (I/F) processor 1A and OS/system software 1B. Reference numeral 2 denotes a user interface such as a keyboard for interactive processing. Reference numeral 3 denotes control software having a tester control processor 3A and a tester utility 3B for activating a Shmoo plot tool. Reference numeral 4 denotes a tester hardware that is controlled by the tester control processor 3A. Reference numeral 5 denotes a device under test.

Reference numeral 6 denotes a relief analysis apparatus connected to the tester hardware 4 which can perform a pre-LT test and that the tester hardware 4 and the relief analysis apparatus 6 are controlled by the tester control processor 3A.

In a pre-LT test that is performed by the tester hardware 4, a memory device is subjected to a function test. If the judgment result is “defective,” defective bit information is transferred to the relief analysis apparatus 6 and it judges whether the memory device can be turned into a good one by replacing defective memory cells with redundant ones. If memory-cell-replaceable, the memory device is judged to be a repair-good device and the judgment result is transferred to the tester hardware 4.

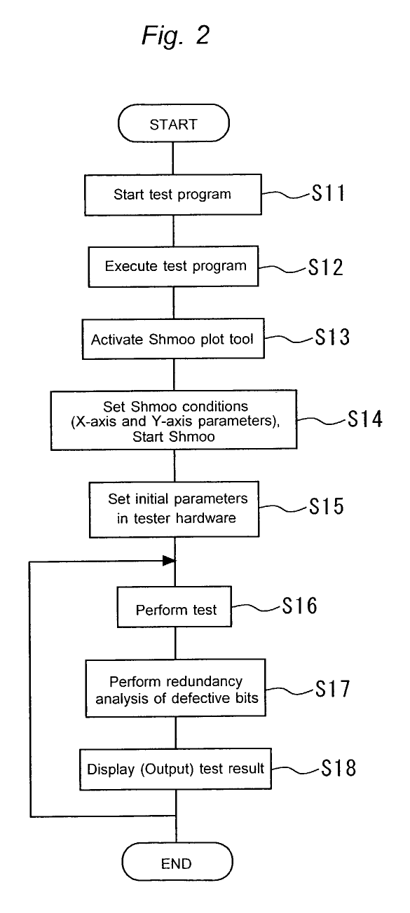

FIG. 2 is a flowchart showing a Shmoo plot execution procedure according to First Embodiment of the present invention. At step S11, a test program is started according to an instruction from the user interface 2. At step S12, the test program is executed. At step S13, the Shmoo plot tool is activated. At step S14, Shmoo conditions, for example X-axis and Y-axis parameters, are set through the user interface 2 in an interactive manner and Shmoo plot is started. At step S15, initial parameter values are set in the tester hardware 4. At step S16, a test is performed.

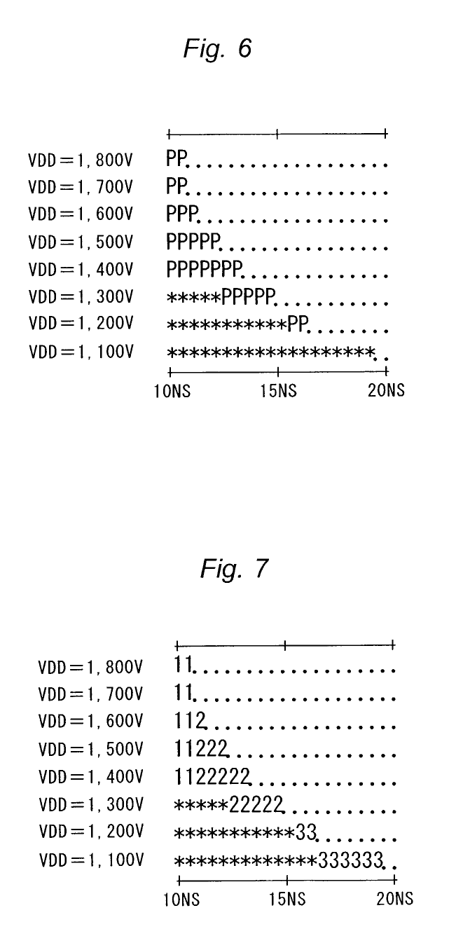

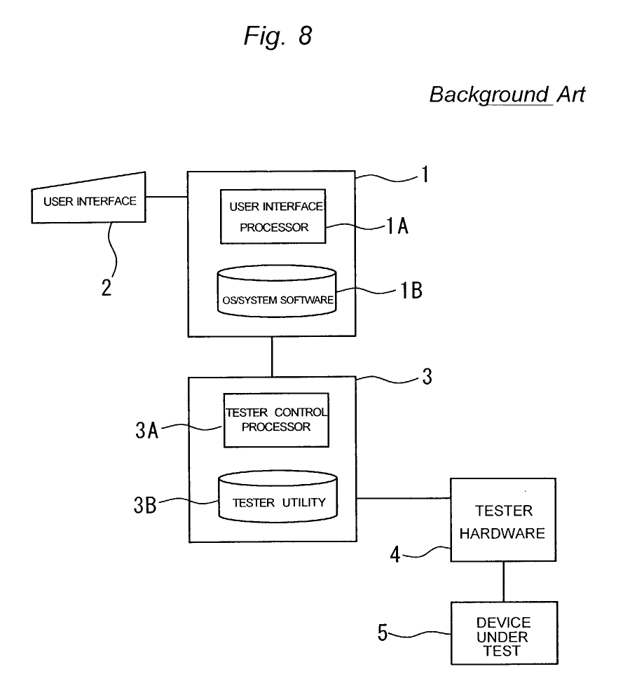

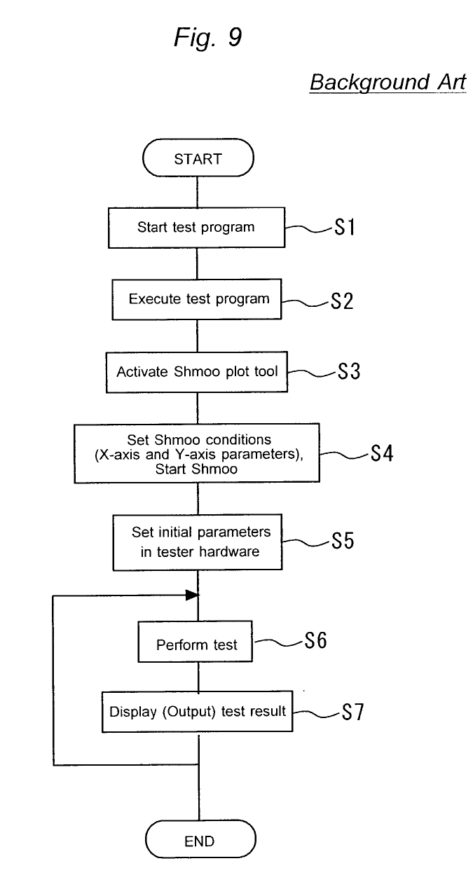

If a judgment result “defective” has occurred in the test, a relief analysis is performed at step S17. At step S18, a test result including a relief analysis result is displayed. The process returns to step S16 after the values of the X-axis and Y-axis parameters are changed, and a similar test including a relief analysis is repeated. Test results are displayed (output) in the form of a plot as shown in FIG. 6.

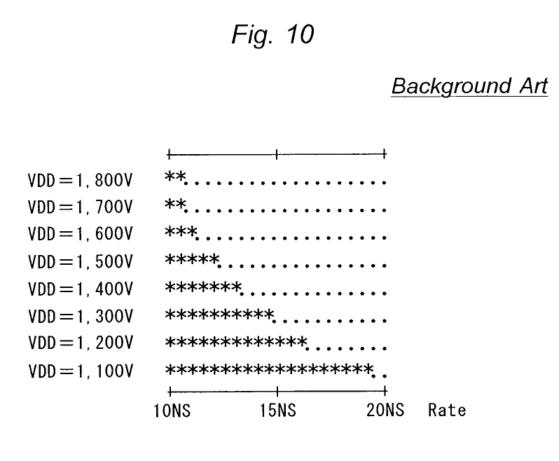

FIG. 6 has the same X-axis and Y-axis parameters as FIG. 10 does. The plot of FIG. 6 is different from that of FIG. 10 in that among judgment results “fails” ones for which it was judged at step S17 in FIG. 2 that the memory device could turn into a repair-good one are discriminated from the other judgment results “fails” by using symbol “P” rather than symbol “*” for a fail.

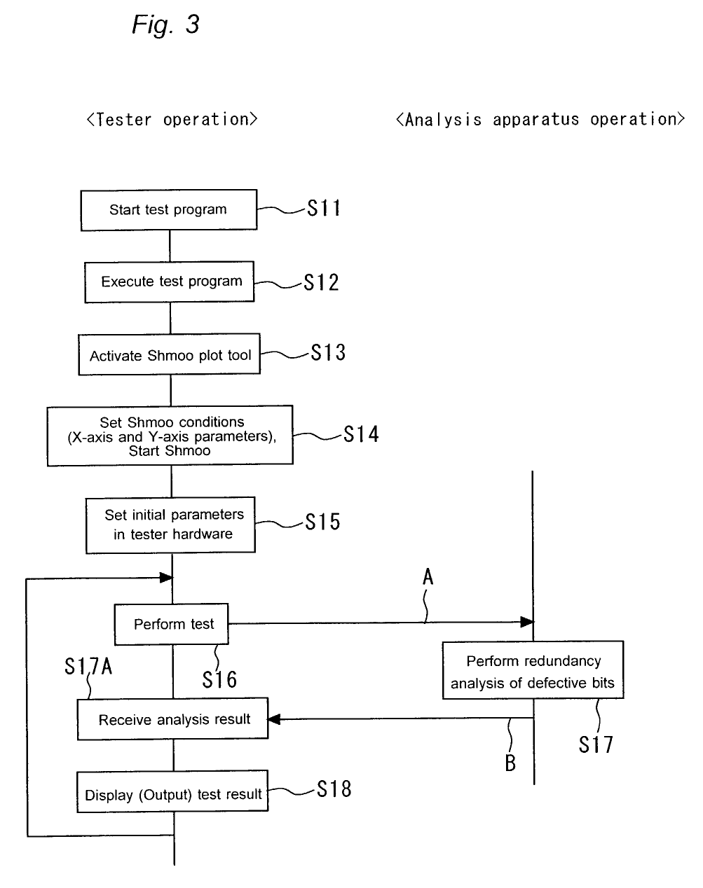

More specifically, each step in the flowchart of FIG. 2 is executed in a manner shown in a flowchart of FIG. 3. In FIG. 3, the operation flows of the tester and the relief analysis apparatus 6 are separated from each other. Steps in FIG. 3 having the same or corresponding steps in FIG. 2 are given the same reference symbols as the latter. If a judgment result “defective” occurs at step S16 which performs a Shmoo plot test, fail information as a test result is transferred to the relief analysis apparatus 6, as arrow A shows. At step S17, a redundancy analysis is performed on defective bits. In other words, a redundancy analysis of defective bits is performed. If it is judged that the memory device can be turned into a repair-good one, such an analysis result is transferred to the tester, as arrow B shows. At step S17A, the tester receives the analysis result. At step S18, a display as shown in FIG. 6 is made. The process returns to step S16 after the values of the X-axis and Y-axis parameters are changed, and a similar test is repeated.

The judgment results shown in FIG. 6 are displayed one for each test; the display of FIG. 6 is completed after a lot of tests are performed while the parameter values are changed.

Second Embodiment

Next, Second Embodiment of the present invention will be described. The tester system will not be described because it is the same as in First Embodiment.

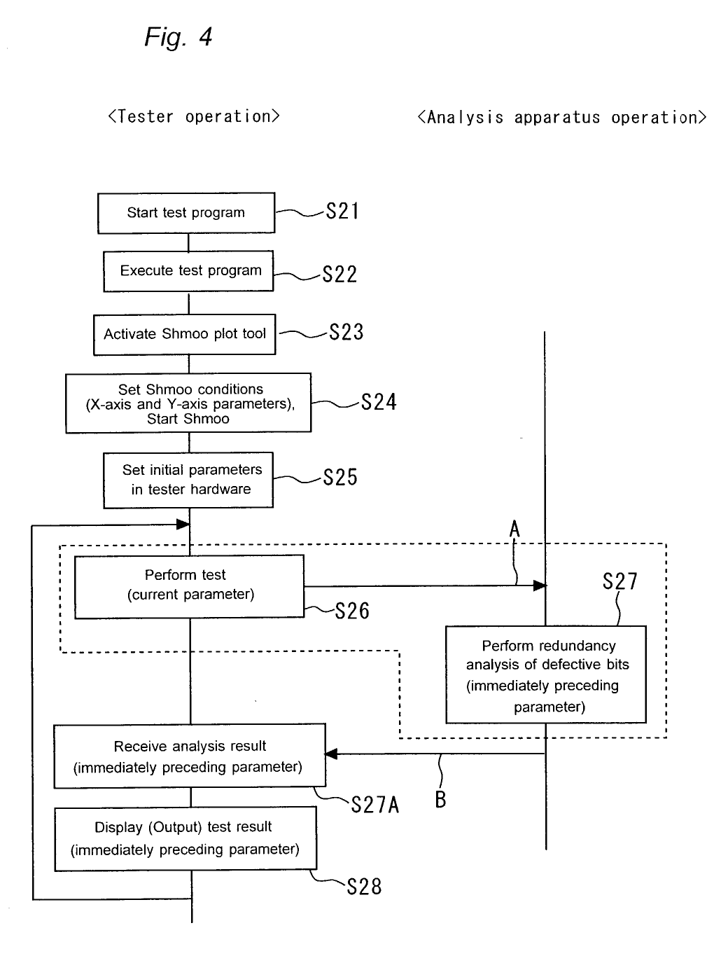

FIG. 4 is a flowchart showing a Shmoo plot execution procedure according to Second Embodiment of the present invention. In Second Embodiment, to shorten the Shmoo plot execution time, the Shmoo plot test and the redundancy analysis are performed parallel with each other. Steps S21-S25 in the flowchart of FIG. 4 are the same as steps S21-S25 in the flowchart of FIG. 3 and hence will not be described.

At step S26, a Shmoo plot test is performed. If a judgment result “defective” occurs, fail information as a test result is transferred to the relief analysis apparatus 6, as arrow A shows. At step S27, a redundancy analysis is performed on defective bits. At this time, in the tester side, a Shmoo plot test is performed by using next parameter values (step S26). Stated from the viewpoint of the operation of the tester, a test is performed at step S26 by using parameter values that are currently set and, at the same time, the relief analysis apparatus 6 performs a redundancy analysis based on a test result (fail information) for immediately preceding parameter values. If it is judged by the redundancy analysis of step S27 that the memory device can be turned into a repair-good one, the analysis result is transferred to the tester, as arrow B shows. The analysis result is received by the tester at step S27A. At step S28, the test result for the immediately preceding parameter values is displayed (output) at a prescribed position in the plot of FIG. 6. The process returns to step S26 after the values of the X-axis and Y-axis parameters are changed. In the above-described manner, steps S26 and S27 are executed parallel with each other, whereby the Shmoo plot execution time can be shortened.

Third Embodiment

Next, Third Embodiment of the present invention will be described. The tester system will not be described because it is the same as in First Embodiment.

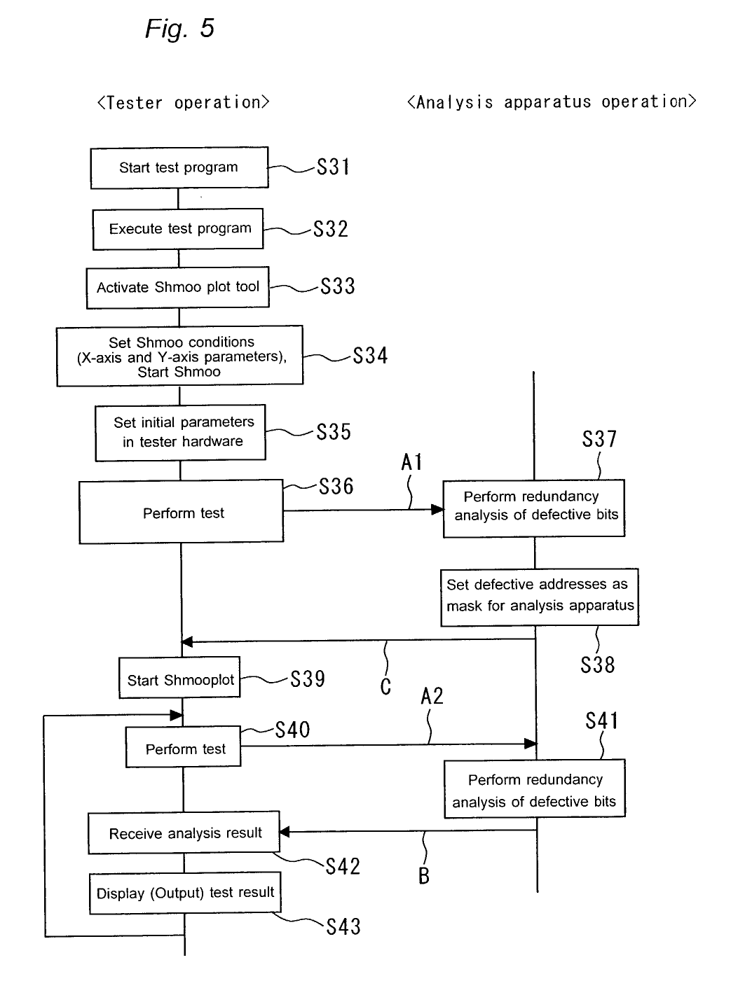

FIG. 5 is a flowchart showing a Shmoo plot execution procedure according to Third Embodiment of the present invention. In this embodiment, a mask for defective addresses or a defective bit line that has been found by a redundancy analysis is set for the relief analysis apparatus 6, whereby the relief analysis apparatus 6 is caused to recognize that no defects exist in the mask-set region and to perform a good/no good judgment based on whether a defective bit exists in the regions excluding the mask-set region. At the same time, an information indicating the mask-set region is transferred to the tester, whereby a Shmoo plot is obtained in such a manner that the memory device is judged good in the mask-set region in Shmoo plot tests.

At step S31 in the flowchart of FIG. 5, mask setting conditions are added to conditions that are similar to ones that are set in each of the above embodiments. Steps S32-S35 are the same as steps S12-S15 in the flowchart of FIG. 3 and hence will not be described.

At step S36, a test is performed by using certain set parameter values. If a judgment result “defective” occurs, fail information as a test result is transferred to the relief analysis apparatus 6, as arrow A1 shows. At step S37, defective bits are subjected to a redundancy analysis. If defective bits are found, at step S38 their addresses or defective bit line is set as mask data for the relief analysis apparatus 6. An information that the mask has been set is sent to the tester, as arrow C shows.

The execution of step S36 is suspended until completion of setting of a mask. The defective bits on the line for which the mask has been set are disregarded in the redundancy analysis and the memory device is judged good for those detective bits.

On the tester side, after reception of the mask setting information, Shmoo plot is started at step S39. A test is performed at step S40. In the test, the memory device is judged good for the mask-set region and the other regions are subjected to the test. If a judgment result “defective” occurs, fail information is transferred to the relief analysis apparatus 6, as arrow A2 shows. A redundancy analysis is performed at step S41. If it is judged by the redundancy analysis of step S41 that the memory device can be turned into a repair-good one, an analysis result is transferred to the tester as arrow B shows. The analysis result is received by the tester at step S42. At step S43, the test result is displayed (output) at a prescribed position in the plot of FIG. 6.

Setting a mask in the above-described manner provides an advantage that the Shmoo plot execution time is shortened, because it becomes unnecessary to perform, for a mask-set region, complex processing of a relievable/unrelievable judgment in a redundancy analysis.

In displaying (outputting) test results, instead of indicating test results “repair-good device” by symbol “P,” it is possible to subdivide relief address information of repair-good devices, give codes to resulting pieces of address information, and display those codes. A Shmoo plot of FIG. 7 is an example of such a case, in which numerals “1,” “2,” and “3” are codes.

This invention, when practiced illustratively in the manner described above, provides the following major effects:

Shmoo plot evaluation method with a relief analysis according to the present invention in a tester enables Shmoo plot evaluation for repair-good devices.

Another Shmoo plot evaluation method with a relief analysis according to the present invention in a tester makes it possible to shorten the Shmoo plot execution time.

A further Shmoo plot evaluation method with a relief analysis according to the present invention in a tester makes it possible to eliminate complex processing of a relievable/unrelievable judgment in a redundancy analysis and to thereby shorten the Shmoo plot execution time.

Any one of the above Shmoo plot evaluation methods makes it possible to obtain Shmoo plot data that includes the degree of relief by a redundancy analysis.

Any one of the above Shmoo plot evaluation methods makes it possible to obtain Shmoo plot data that includes relief address information and the degree of relief.

Further, the present invention is not limited to these embodiments, but variations and modifications may be made without departing from the scope of the present invention.

The entire disclosure of Japanese Patent Application No. 2002-150594 filed on May 24, 2002 containing specification, claims, drawings and summary are incorporated herein by reference in its entirety.

What is claimed is:

1. A Shmoo plot evaluation method in a tester comprising a Shmoo plot tool and a relief analysis apparatus, comprising the steps of:
setting Shmoo conditions in the Shmoo plot tool and starting Shmoo plot;
setting initial parameter values in a tester hardware;
performing a test using set parameter values;
transferring, to the relief analysis apparatus, fail information that is produced as a result of the test;
causing the relief analysis apparatus to perform a relief analysis on defective bits;
transferring a result of the relief analysis to the Shmoo plot tool; and
causing the Shmoo plot tool to output a result of the relief analysis as Shmoo data,
wherein said step of performing a test and said following steps are repeated while the set parameter values are changed.

2. A Shmoo plot evaluation method in a tester comprising a Shmoo plot tool and a relief analysis apparatus, comprising the steps of:
setting Shmoo conditions in the Shmoo plot tool and starting Shmoo plot;
setting initial parameter values in a tester hardware;
performing a test using set parameter values;
transferring, to the relief analysis apparatus, fail information that is produced as a result of the test;
causing the relief analysis apparatus to perform a relief analysis on defective bits and causing the Shmoo plot tool to perform, parallel with the relief analysis, a next test after the set parameter values are changed;
transferring a result of the relief analysis to the Shmoo plot tool; and
causing the Shmoo plot tool to output a result of the relief analysis as Shmoo data,
wherein said step of performing a test and said following steps are repeated while the set parameter values are changed.

3. A Shmoo plot evaluation method in a tester comprising a Shmoo plot tool and a relief analysis apparatus, comprising the steps of:
setting Shmoo conditions in the Shmoo plot tool and starting Shmoo plot;
setting initial parameter values in a tester hardware;
performing a test using set parameter values;
transferring, to the relief analysis apparatus, fail information that is produced as a result of the test;
causing the relief analysis apparatus to perform a relief analysis on defective bits;
setting a mask for masking defective addresses for the relief analysis apparatus;
transferring, to the Shmoo plot tool, completion of setting of the mask;
causing the Shmoo plot tool to start a Shmoo plot test;
transferring, to the relief analysis apparatus, fail information that is produced as a result of the Shmoo plot test;
causing the relief analysis apparatus in which the mask is set to perform a relief analysis on defective bits;
transferring a result of the relief analysis to the Shmoo plot tool; and
causing the Shmoo plot tool to output, as Shmoo data, a result of the relief analysis with the mask,
wherein said step of causing the Shmoo plot tool to start a Shmoo plot test and said following steps are repeated while the set parameter values are changed.

4. The Shmoo plot evaluation method according to claim 1, wherein the Shmoo data that is output from the Shmoo plot tool is displayed in such a manner that a pass as a result of the relief analysis and a fail are indicated in different manners.

5. The Shmoo plot evaluation method according to claim 2, wherein the Shmoo data that is output from the Shmoo plot tool is displayed in such a manner that a pass as a result of the relief analysis and a fail are indicated in different manners.

6. The Shmoo plot evaluation method according to claim 3, wherein the Shmoo data that is output from the Shmoo plot tool is displayed in such a manner that a pass as a result of the relief analysis and a fail are indicated in different manners.

7. The Shmoo plot evaluation method according to claim 4, wherein a pass as a result of the relief analysis is indicated by a relief code corresponding to relief address information.

8. The Shmoo plot evaluation method according to claim 5, wherein a pass as a result of the relief analysis is indicated by a relief code corresponding to relief address information.

9. The Shmoo plot evaluation method according to claim 6, wherein a pass as a result of the relief analysis is indicated by a relief code corresponding to relief address information.
